(19) United States
(12) Patent Application Publication
(10) Pub. No.: US 2026/0239737 A1
(43) Pub. Date: Aug. 13, 2026

(54) CARRIER SUBSTRATE STRUCTURE AND METHOD OF MANUFACTURING INTEGRATED CIRCUIT DEVICE USING THE SAME

(71) Applicant: Samsung Electronics Co., Ltd., Suwon-si (KR)

(72) Inventors: Taeyeong KIM, Suwon-si (KR); Yeonsu LEE, Suwon-si (KR); Nungpyo HONG, Suwon-si (KR); Daesan CHOI, Suwon-si (KR); Bumki MOON, Suwon-si (KR); Pil-Kyu KANG, Suwon-si (KR)

(73) Assignee: Samsung Electronics Co., Ltd., Suwon-si (KR)

(21) Appl. No.: 19/535,000

(22) Filed: Feb. 10, 2026

(30) Foreign Application Priority Data
Feb. 12, 2025 (KR) 10-2025-0018124

(51) Int. Cl. H10D 86/01

(52) U.S. Cl. CPC H10D 86/0214

(57) ABSTRACT

A method of manufacturing an integrated circuit device, includes forming a de-bonding layer on a carrier substrate, the de-bonding layer including a metallic oxide, forming a light absorbing layer on the de-bonding layer, forming a bonding layer on the light absorbing layer, and bonding an integrated circuit substrate structure to the bonding layer, and irradiating the carrier substrate with light to separate the de-bonding layer from the light absorbing layer. The de-bonding layer has a thermal expansion coefficient that is 10 times or greater than 10 times a thermal expansion coefficient of the light absorbing layer.

### CROSS-REFERENCE TO RELATED APPLICATIONS

This application claims priority from Korean Patent Application No. 10-2025-0018124, filed on February 12, 2025, in the Korean Intellectual Property Office, the disclosure of which being incorporated by reference herein in its entirety.

### BACKGROUND

Example embodiments relate to a carrier substrate structure and a method of manufacturing an integrated circuit device using the same.

In order to manufacture integrated circuits utilizing front and back sides of a wafer, a substrate bonding process may be performed in which two or more substrates are bonded to each other. The substrate bonding process can be performed to improve the packaging density of integrated circuit devices. For example, with an increase in a mounting density of integrated circuit devices, a semiconductor module having a structure in which integrated circuit devices are stacked can be advantageous in reducing the wiring length between integrated circuit devices and in high-speed signal processing. The substrate bonding process can be performed in a wafer-to-wafer manner, directly bonding two wafers without a separate medium. Further, a de-bonding process may be performed to separate the two bonded wafers again to form a device structure on both sides of the wafer.

### SUMMARY

It is an aspect to provide a carrier substrate structure by which reliability on de-bonding is improved.

It is another aspect to provide a method of manufacturing an integrated circuit device of which manufacturing efficiency is improved.

According to an aspect of one or more embodiments, there is provided a method of manufacturing an integrated circuit device, the method comprising forming a de-bonding layer on a carrier substrate, the de-bonding layer comprising a metallic oxide; forming a light absorbing layer on the de-bonding layer; forming a bonding layer on the light absorbing layer; bonding an integrated circuit substrate structure to the bonding layer; and irradiating the carrier substrate with light to separate the de-bonding layer from the light absorbing layer. The de-bonding layer has a thermal expansion coefficient that is 10 times or greater than 10 times a thermal expansion coefficient of the light absorbing layer.

According to another aspect of one or more embodiments, there is provided a method of manufacturing an integrated circuit device, the method comprising forming a carrier substrate structure comprising a de-bonding layer, a light absorbing layer and a bonding layer that are sequentially stacked on a carrier substrate; bonding an integrated circuit substrate structure on the bonding layer, the integrated circuit substrate structure comprising the integrated circuit device; forming a device structure on the integrated circuit substrate structure, the device structure being electrically connected with the integrated circuit device on the integrated circuit substrate structure; and irradiating the carrier substrate structure with light to de-bond the de-bonding layer and the light absorbing layer. The de-bonding layer comprises a metallic oxide, and the de-bonding layer has a thermal expansion coefficient that is 10 times or greater than 10 times a thermal expansion coefficient of the light absorbing layer.

According to yet another aspect of one or more embodiments, there is provided a method of manufacturing an integrated circuit device, the method comprising bonding an integrated circuit substrate structure on a carrier substrate structure comprising a de-bonding layer, a light absorbing layer, a protecting layer, a buffer layer and a bonding layer that are sequentially stacked on a carrier substrate, the integrated circuit substrate structure comprising the integrated circuit device; and irradiating the carrier substrate structure with light having a wavelength of 9300 nm or greater to de-bonding the de-bonding layer from the light absorbing layer. The de-bonding layer comprises a metallic oxide, the de-bonding layer has a thermal expansion coefficient that is 10 times or greater than 10 times a thermal expansion coefficient of the light absorbing layer, the de-bonding layer and the light absorbing layer absorb the light, and the protecting layer reflects the light.

### BRIEF DESCRIPTION OF THE FIGURES

These and/or other aspects will become apparent and more readily appreciated from the following description of example embodiments, taken in conjunction with the accompanying drawings, in which:

FIG. 1 is a schematic drawing illustrating a carrier substrate structure according to an example embodiment;

FIG. 2 is an enlarged view of a part P of FIG. 1;

FIG. 3 is a schematic drawing illustrating a carrier substrate structure according to an example embodiment;

FIG. 4 is a schematic drawing illustrating a carrier substrate structure according to an example embodiment;

FIG. 5 is an enlarged view of a part Q of FIG. 4; and

FIGS. 6 to FIG. 13 are schematic drawings illustrating intermediate operations for explaining a method of manufacturing an integrated circuit device according to an example embodiment.

### DETAILED DESCRIPTION

The terms or words used in this specification and claims should be interpreted with meaning and concept consistent with the technical idea of the present disclosure based on the principle that the inventor may appropriately define the concept of terms in order to explain embodiments in the best way. The example embodiments described in this specification and the configurations shown in the drawings are only examples, and do not necessarily represent the entire technical idea of the present disclosure. Accordingly, at the time of filing the present disclosure, there may be various equivalents and modifications that can replace the embodiments.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

In the present disclosure, terms such as “first,” “second” and so on may be used to describe various components. However, the components are not limited by these terms, and these terms may be used for the purpose of distinguishing one component from another. Within the scope of the technical idea of the present disclosure, a “first” component may be named as a “second” component. Similarly, the “second” component may also be named the “first” component. Further, the shape and size of components may be exaggerated in the drawings to improve the clarity of explanation.

Further, in the following description, expressions such as an upper side, top, a lower side, bottom, a side, front and a back side are expressed based on directions shown in the drawing. If the direction of the object changes, the directions of the expressions also may be expressed differently. As used in this specification, a phrase using the form “at least one of A, B, or C” includes within its scope “only A”, “only B”, “only C”, “A and B”, “A and C”, “B and C” and “A, B, and C.”

Hereinafter, example embodiments will be described with reference to the attached drawings.

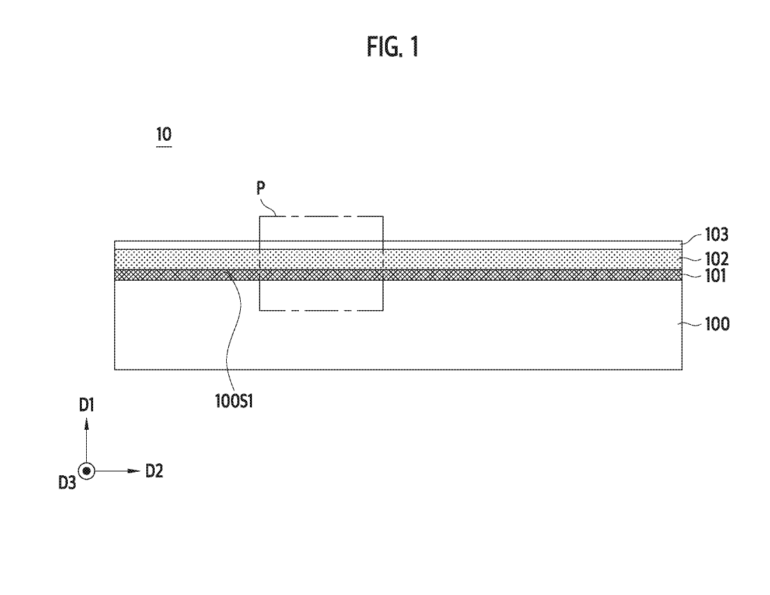

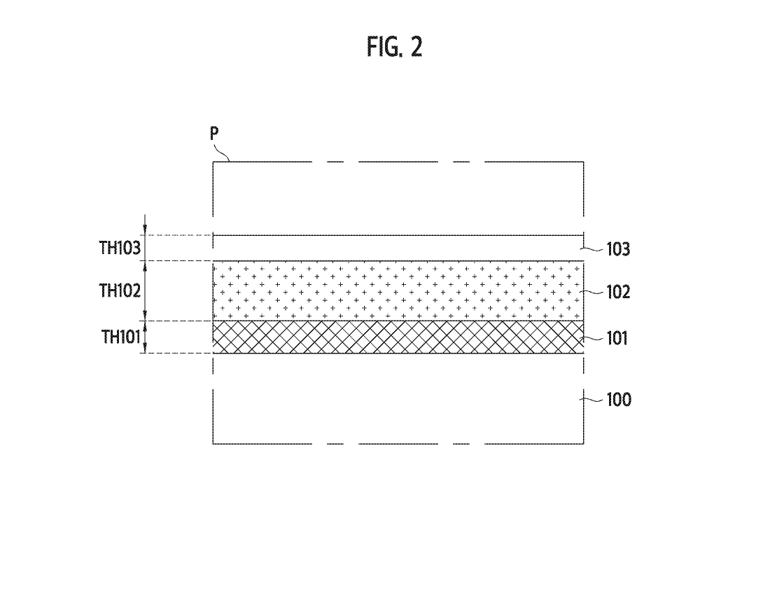

FIG. 1 is a schematic drawing illustrating a carrier substrate structure according to an example embodiment. FIG. 2 is an enlarged view of a part P of FIG. 1.

Referring to FIGS. 1 and FIG. 2, a carrier substrate structure 10 may include a carrier substrate 100, a de-bonding layer 101, a light absorbing layer 102 and a bonding layer 103.

According to some example embodiments, the carrier substrate structure 10 may support an integrated circuit device in the process of manufacturing the integrated circuit device. For example, the carrier substrate structure 10 may be bonded to a substrate of an integrated circuit device to support the integrated circuit device.

According to some example embodiments, the carrier substrate 100 may be a glass substrate, a ceramic substrate or a plastic substrate, but embodiments are not limited thereto. In some example embodiments, the carrier substrate 100 may include a resin impregnated in a core material such as glass fiber (e.g., glass cloth and/or glass fabric) with an inorganic filler, for example, prepreg, Ajinomoto Build-up Film (ABF), FR-4, and/or Bismaleimide Triazine (BT).

According to some example embodiments, the carrier substrate 100 may be a silicon substrate. The carrier substrate 100 may include bulk silicon or silicon-on-insulator (SOI). The carrier substrate 100 may include silicon germanium, silicon germanium on insulator (SGOI), indium antimonide, lead telluride, indium arsenide, indium phosphide, gallium arsenide or gallium antimonide. However, embodiments are not limited thereto.

According to some example embodiments, the carrier substrate 100 may be a support substrate that is bonded to the substrate of an integrated circuit device in the process of manufacturing the integrated circuit device.

According to some example embodiments, the de-bonding layer 101 may be disposed on the carrier substrate 100. The de-bonding layer 101 may be placed on a first surface 100S1 of the carrier substrate 100 in a first direction D1. The first direction D1 may be a direction intersecting the first surface 100S1 of the carrier substrate 100. In an embodiment, the first direction D1 may be orthogonal to the first surface 100S1 of the carrier substrate 100. That is, the carrier substrate 100 may extend in a second direction D2 and a third direction D3, and the first direction D1 may be orthogonal to the second and third directions D2 and D3. The de-bonding layer 101 may cover the first surface 100S1 of the carrier substrate 100. The de-bonding layer 101 may be in contact with the carrier substrate 100. The de-bonding layer 101 may be in contact with the first surface 100S1 of the carrier substrate 100. The de-bonding layer 101 may be positioned between the carrier substrate 100 and the light absorbing layer 102. The de-bonding layer 101 may be in contact with the light absorbing layer 102.

According to some example embodiments, the de-bonding layer 101 may include a metal oxide. In an example embodiment, the de-bonding layer 101 may include either TiO or AlO. A thermal expansion coefficient of the de-bonding layer 101 may be greater than a thermal expansion coefficient of the light absorbing layer 102. In an example embodiment, the thermal expansion coefficient of the de-bonding layer 101 may be 10 times the thermal expansion coefficient of the light absorbing layer 102 or may be greater than 10 times the thermal expansion coefficient of the light absorbing layer 102. In an example embodiment, the thermal expansion coefficient of the de-bonding layer 101 may be 12 times the thermal expansion coefficient of the light absorbing layer 102 or may be greater than 12 times the thermal expansion coefficient of the light absorbing layer 102. In an example embodiment, the de-bonding layer 101 may absorb light with a wavelength of 9000 nm or greater. For example, in some example embodiments, the de-bonding layer 101 may absorb light with a wavelength of 9300 nm or greater.

According to some example embodiments, the light absorbing layer 102 may be placed on the de-bonding layer 101. The light absorbing layer 102 may be in contact with the de-bonding layer 101. The light absorbing layer 102 may be placed between the de-bonding layer 101 and the bonding layer 103.

According to some example embodiments, the light absorbing layer 102 may include at least one of silicon oxide, silicon nitride, silicon oxynitride (SiON), silicon oxycarbonitride (SiOCN), tetra ethyl ortho silicate (TEOS) or combinations thereof. In an example embodiment, the light absorbing layer 102 may include TEOS. In an example embodiment, the light absorbing layer 102 may include a silicon oxide. In an example embodiment, the thermal expansion coefficient of the light absorbing layer 102 may be less than the thermal expansion coefficient of the de-bonding layer 101. In an example embodiment, the light absorbing layer 102 may absorb light with a wavelength of 9000 nm or greater. For example, in some example embodiments, the light absorbing layer 102 may absorb light having a wavelength of 9300 nm or greater.

According to some example embodiments, the de-bonding layer 101 and the light absorbing layer 102 may be in contact to form an interface. The contacted de-bonding layer 101 and the light absorbing layer 102 may be separated at the interface by light having a wavelength of 9300 nm or greater. This separation may be due to the difference in thermal expansion coefficients of the de-bonding layer 101 and the light absorbing layer 102. When exposed to light having a wavelength of 9300 nm or greater, there is a large difference in the degree to which the de-bonding layer 101 and the light absorbing layer 102 expand due to heat, and thus the de-bonding layer 101 and the light absorbing layer 102 that are in contact may be de-bonded from each other. The de-bonding layer 101 and the light absorbing layer 102 may be separated at the interface due to the difference in thermal expansion coefficients between the de-bonding layer 101 and the light absorbing layer 102, and thus the reliability of de-bonding of the carrier substrate structure 10 and other substrate structures may be improved. Further, since de-bonding of the carrier substrate structure 10 becomes easier, the manufacturing efficiency of an integrated circuit device using the carrier substrate structure 10 may be improved.

According to some example embodiments, the bonding layer 103 may be placed on the light absorbing layer 102. The bonding layer 103 may include at least one of silicon oxide, silicon nitride, silicon oxynitride (SiON), silicon carbonitride (SiCN), silicon oxycarbonitride (SiOCN), tetra ethyl ortho silicate (TEOS) or combinations thereof. In an example embodiment, the bonding layer 103 may include silicon carbon nitride (SiCN). The bonding layer 103 may be bonded to another substrate structure that is bonded to the carrier substrate structure 10. The bonding layer 103 may be bonded to another substrate structure supported by the carrier substrate structure 10.

According to some example embodiments, as illustrated in FIG. 2, a thickness TH102 of the light absorbing layer 102 may be greater than a thickness TH101of the de-bonding layer 101 and may be greater than a thickness TH103 of the bonding layer 103. The thickness TH102 of the light absorbing layer 102 may be in a range of about 100 nm to about 500 nm. The thickness TH101 of the de-bonding layer 101 may be in a range of about 5 nm to about 100 nm. FIG. 2 illustrates that the thickness TH103 of the bonding layer 103 is smaller than the thickness TH101 of the de-bonding layer 101. However, the embodiments are not limited thereto. For example, the thickness TH103 of the bonding layer 103 may be greater than or equal to the thickness TH101 of the de-bonding layer 101.

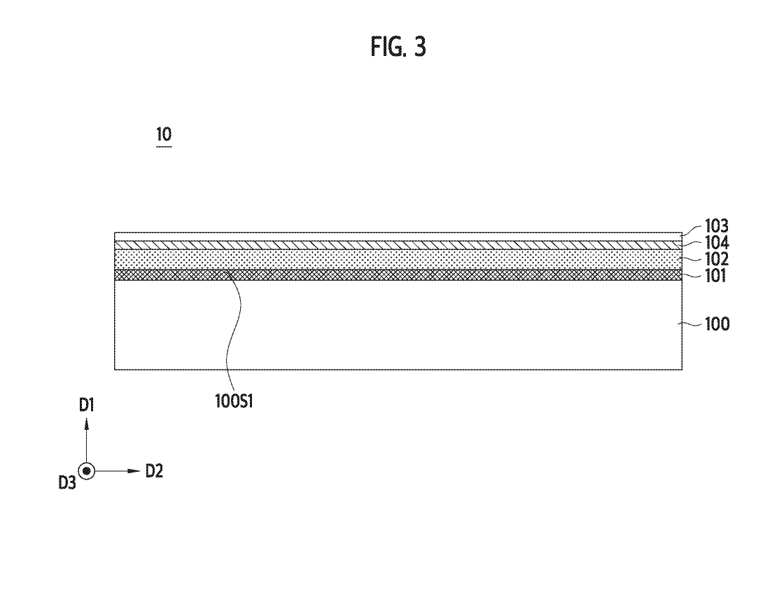

FIG. 3 is a schematic drawing illustrating a carrier substrate structure according to an example embodiment. For convenience of explanation, like reference numbers are used for like layers in FIGS. 1-3, and the differences from those described with reference to FIGS. 1 and FIG. 2 are mainly explained for conciseness.

Referring to FIG. 3, the carrier substrate structure 10 may further include a protecting layer 104. The protecting layer 104 may be placed between the light absorbing layer 102 and the bonding layer 103. The protecting layer 104 may be placed on the light absorbing layer 102.

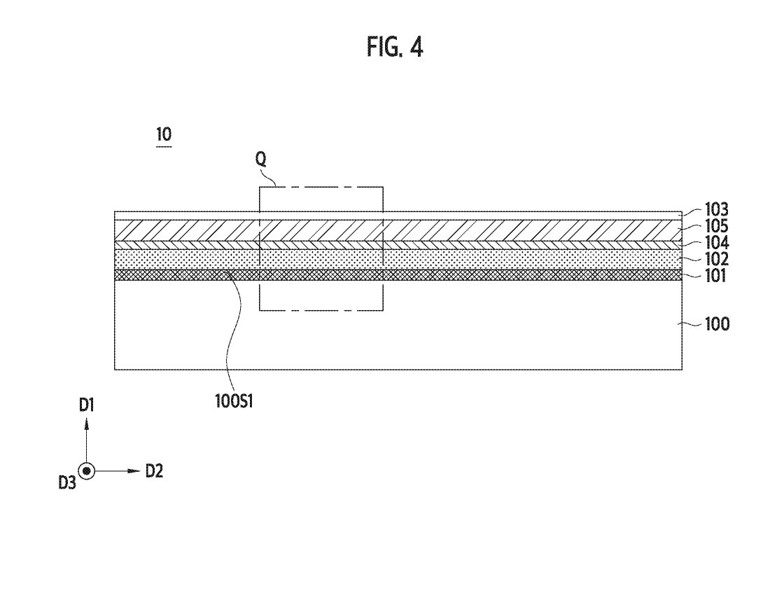

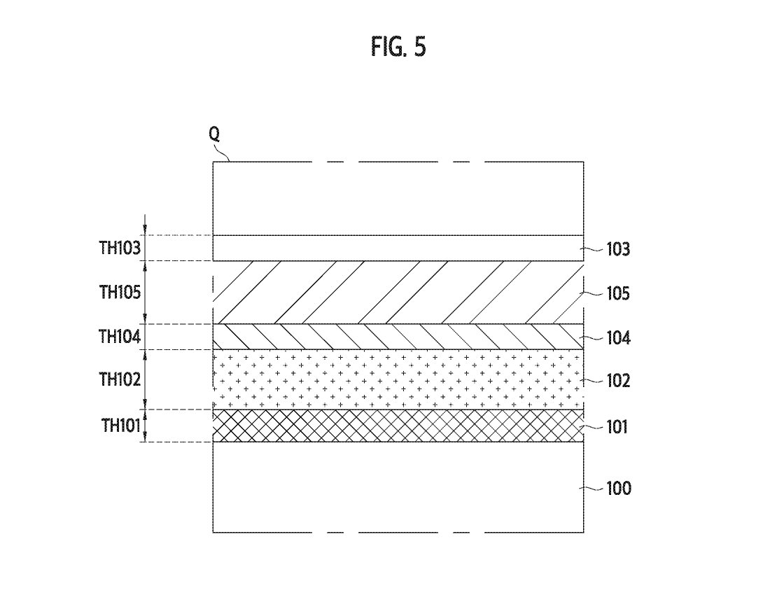

According to some example embodiments, the protecting layer 104 may contain a metal material. In an example embodiment, the protecting layer 104 may include any one of titanium nitride (TiN), tungsten (W), aluminum (Al) or copper (Cu). In an example embodiment, the protecting layer 104 may reflect light with a wavelength of 9000 nm or greater. For example, in some example embodiments, the protecting layer 104 may reflect light with a wavelength of 9300 nm or greater. The protecting layer 104 may reflect light so that the light absorbed by the de-bonding layer 101 and the light absorbing layer 102 is not transmitted to other substrate structures bonded on the bonding layer 103. The protecting layer 104 is described in detail with reference to FIGS. 4 and FIG. 5 below.

FIG. 4 is a schematic drawing illustrating a carrier substrate structure according to an example embodiment. FIG. 5 is an enlarged view of a part Q of FIG. 4. For convenience of explanation, like reference numbers are used for like layers in FIGS. 1-5, and differences from those described with reference to FIGS. 1 to FIG. 3 are mainly explained for conciseness.

Referring to FIGS. 4 and FIG. 5, the carrier substrate structure 10 may include the carrier substrate 100, the de-bonding layer 101, the light absorbing layer 102, the bonding layer 103, the protecting layer 104 and a buffer layer 105. Descriptions on the carrier substrate 100, the de-bonding layer 101, the light absorbing layer 102, and the bonding layer 103 are substantially the same as those described with reference to FIGS. 1 and FIG. 2, and thus repeated description is omitted for conciseness.

According to some example embodiments, the protecting layer 104 and the buffer layer 105 may be placed between the light absorbing layer 102 and the bonding layer 103. The protecting layer 104 and the buffer layer 105 may be placed on the light absorbing layer 102. Descriptions of the protecting layer 104 are substantially the same as for the protecting layer 104 described with reference to FIG. 3, and thus repeated description is omitted for conciseness.

According to some example embodiments, the buffer layer 105 may be placed on top of the protecting layer 104. The buffer layer 105 may cover the protecting layer 104. The buffer layer 105 may be placed between the protecting layer 104 and the bonding layer 103. The buffer layer 105 may include at least one of silicon oxide, silicon nitride, silicon oxynitride (SiON), silicon oxycarbonitride (SiOCN), tetraethyl orthosilicate (TEOS), or combinations thereof. In an example embodiment, the buffer layer 105 may contain TEOS. In an example embodiment, the buffer layer 105 may include silicon oxide. For example, I nsome example embodiments, the buffer layer 105 may contain the same material as the light absorbing layer 102. The buffer layer 105 may suppress heat generated by light provided to the carrier substrate structure 10 from being transferred to another substrate structure bonded on the bonding layer 103.

According to some example embodiments, as illustrated in FIG. 5, a thickness TH105 of the buffer layer 105 may be greater than a thickness TH104 of the protecting layer 104. The thickness TH104 of the protecting layer 104 may be in a range of about 5 nm to about 50 nm. The thickness TH105 of the buffer layer 105 may be in a range of about 100 nm to about 500 nm. For example, in some example embodiments, the thickness TH105 of the buffer layer 105 may be the same as the thickness TH102 of the light absorbing layer 102. However, example embodiments are not limited thereto. In some example embodiments, the thickness TH105 of the buffer layer 105 may be greater than or equal to the thickness TH102 of the light absorbing layer 102.

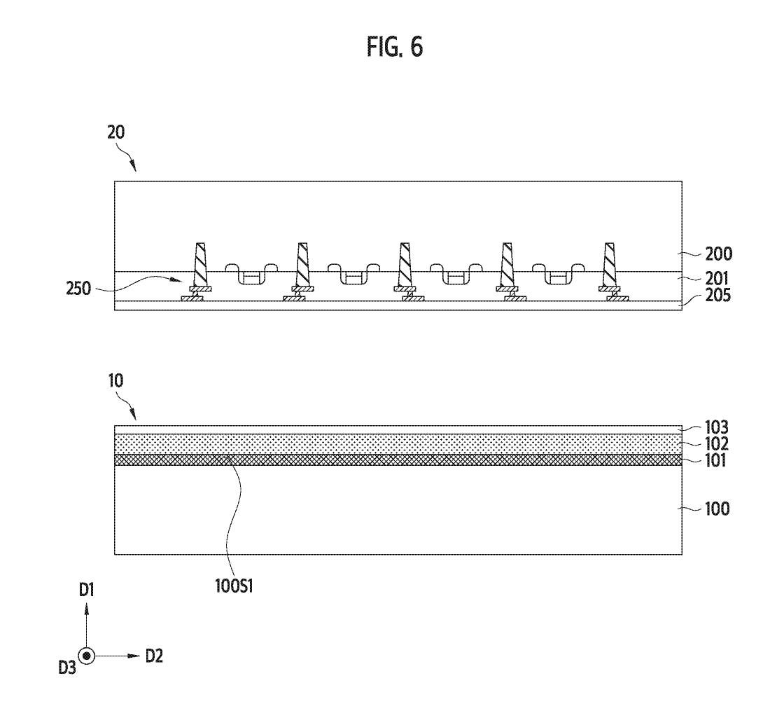

FIGS. 6 to FIG. 13 are schematic drawings illustrating intermediate operations for explaining a method of manufacturing an integrated circuit device according to an example embodiment.

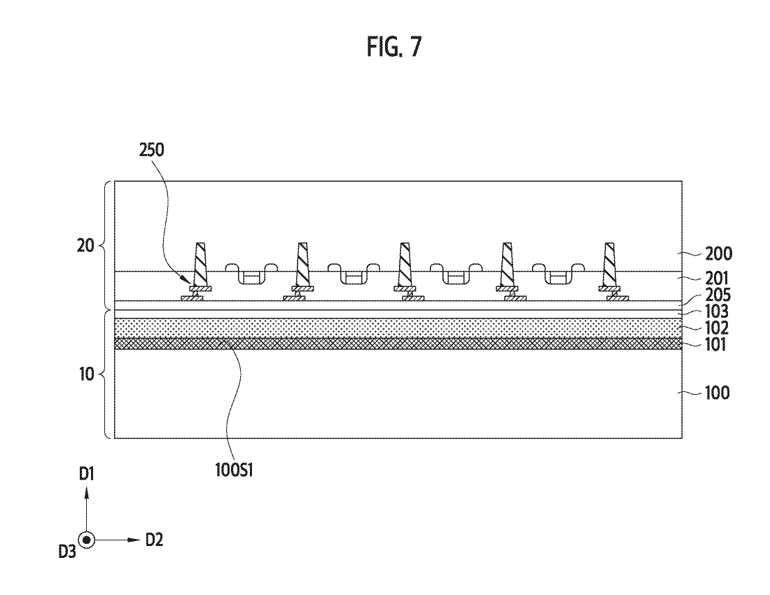

Referring to FIGS. 6 and FIG. 7, the carrier substrate structure 10 may be formed in which the de-bonding layer 101, the light absorbing layer 102 and the bonding layer 103 are sequentially laminated on the carrier substrate 100. An integrated circuit substrate structure 20 including an integrated circuit device 250 may be bonded on the carrier substrate structure 10. The integrated circuit substrate structure 20 may be bonded on the bonding layer 103 of the carrier substrate structure 10.

According to some example embodiments, the carrier substrate structure 10 may include the de-bonding layer 101, the light absorbing layer 102, and the bonding layer 103 sequentially stacked on the carrier substrate 100. Descriptions on the carrier substrate 100, the de-bonding layer 101, the light absorbing layer 102, and the bonding layer 103 are substantially the same as those described with reference to FIGS. 1 and FIG. 2, and thus repeated description is omitted for conciseness. FIGS. 6 and FIG. 7 illustrate that only the de-bonding layer 101, the light absorbing layer 102 and the bonding layer 103 are formed on the carrier substrate 100. However, embodiments are not limited thereto. For example, in some embodiments, as illustrated in FIGS. 3 and FIG. 4, the carrier substrate structure 10 may include the de-bonding layer 101, the light absorbing layer 102, the protecting layer 104, the buffer layer 105 and the bonding layer 103 sequentially stacked on the carrier substrate 100.

According to some example embodiments, the integrated circuit substrate structure 20 may include a device substrate 200, an insulation layer 201, a bonding layer 205 and the integrated circuit device 250.

According to some example embodiments, the device substrate 200 may be bulk silicon or silicon-on-insulator (SOI). In an example embodiment, the device substrate 200 may be a silicon substrate. In an example embodiment, the device substrate 200 may include silicon germanium, silicon germanium on insulator (SGOI), indium antimonide, lead telluride, indium arsenide, indium phosphide, gallium arsenide, or gallium antimonide. However, embodiments are not limited thereto.

According to some example embodiments, the device substrate 200 may include a conductive region, or, a doped well or a doped structure. The device substrate 200 may have various device isolation structures, such as a shallow trench isolation (STI) structure.

According to some example embodiments, the insulation layer 201 may be disposed on one surface of the device substrate 200. The insulation layer 201 may cover one surface of the device substrate 200 facing the carrier substrate structure 10 in the first direction D1. The device substrate 200 and the insulation layer 201 may be arranged relative to each other in the first direction D1. The insulation layer 201 may surround the integrated circuit device 250. The insulation layer 201 may cover at least a portion of the integrated circuit device 250.

According to some example embodiments, the insulation layer 201 may include at least one of silicon oxide, silicon nitride, silicon oxynitride (SiON), silicon oxycarbonitride (SiOCN), TEOS or combinations thereof. In an example embodiment, the insulation layer 201 may include a material different from the device substrate 200.

According to some example embodiments, the bonding layer 205 may be disposed on one surface of the device substrate 200. The bonding layer 205 may cover one side of the insulation layer 201. The bonding layer 205 may include at least one of silicon oxide, silicon nitride, silicon oxynitride (SiON), silicon oxycarbonitride (SiOCN) or combinations thereof. The bonding layer 205 may include a non-conductive film (NCF), a non-conductive paste (NCP), an insulating polymer, or an epoxy resin, but embodiments are not limited thereto. In an example embodiment, the bonding layer 205 may be a tape for fixing the integrated circuit substrate structure 20 onto the carrier substrate structure 10. In an example embodiment, the bonding layer 205 may be, for example, a tape containing an epoxy component. In some example embodiments, the bonding layer 205 may include a silicon oxide.

According to some example embodiments, the integrated circuit device 250 may include a plurality of semiconductor devices of various types. The integrated circuit device 250 may include various microelectronic devices, for example, metal-oxide-semiconductor field effect transistors (MOSFETs) such as complementary metal-insulator-semiconductor (CMOS) transistors, system large scale integration (LSI), flash memories, DRAMs, SRAMs, EEPROMs, PRAMs, MRAMs, RRAMs, image sensors such as CMOS imaging sensor (CIS), a micro-electro-mechanical system (MEMS), active devices, passive devices and so on.

According to some example embodiments, the integrated circuit device 250 may be a volatile memory device, for example, dynamic random access memory (DRAM) or static random access memory (SRAM). In some example embodiments, the integrated circuit device 250 may be a non-volatile memory device such as flash memory, phase-change RAM (PRAM), magnetoresistive RAM (MRAM), ferroelectric RAM (FeRAM), or resistive RAM (RRAM). In some example embodiments, the integrated circuit device 250 may include logic elements. The integrated circuit device 250 may be a component that constitutes at least a portion of an application processor (AP), such as central processing unit (CPU), graphic processing unit (GPU), field-programmable gate array (FPGA), a digital signal processor, a cryptographic processor, a microprocessor, or a microcontroller. However, embodiments are not limited thereto.

According to some example embodiments, the bonding layer 205 of the integrated circuit substrate structure 20 and the bonding layer 103 of the carrier substrate structure 10 may be bonded to each other, as illustrated in FIG. 7.

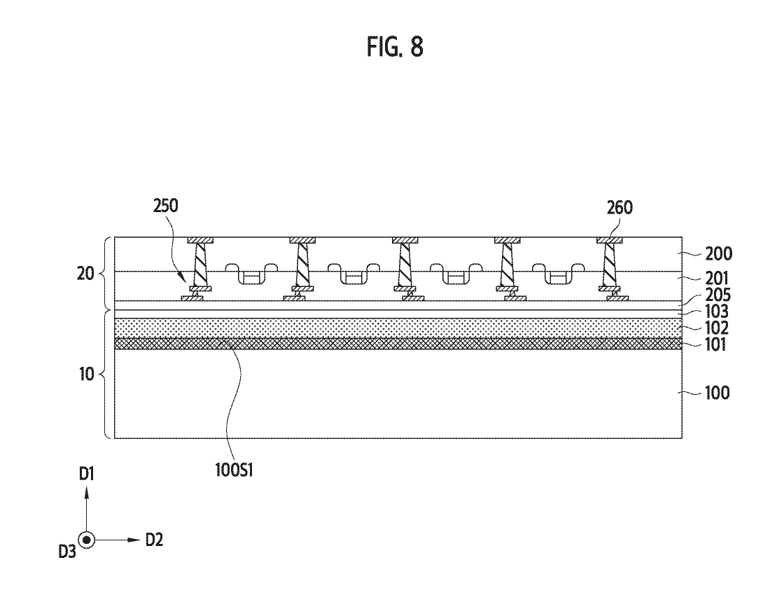

Referring to FIG. 8, a device structure 260 electrically connected to the integrated circuit device 250 may be formed on the integrated circuit substrate structure 20. For example, at least a portion of the device substrate 200 may be removed, and the integrated circuit device 250 may be exposed on one side of the integrated circuit substrate structure 20 by the removal of the portion of the device substrate 200. For example, at least a portion of the device substrate 200 may be removed through a chemical mechanical polishing (CMP) process. At least a portion of the device substrate 200 may be removed on a surface that is placed to be opposite to one surface of the device substrate 200 facing the carrier substrate structure 10, where the carrier substrate structure 10 supports the integrated circuit substrate structure 20. The device structure 260 may be formed to be electrically connected with the integrated circuit device 250 that is exposed by at least a portion of the device substrate 200 being removed.

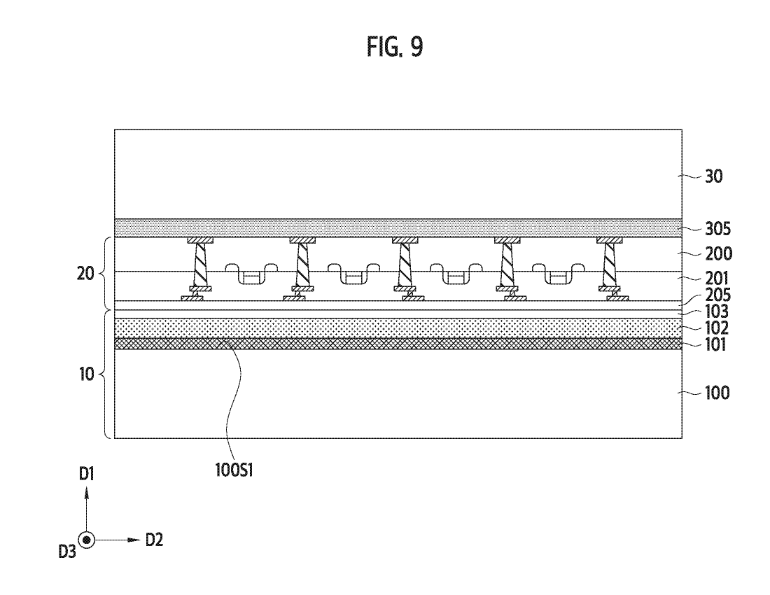

Referring to FIG. 9, a bonding layer 305 and a supporting substrate 30 may be formed on the carrier substrate structure 10 and the integrated circuit substrate structure 20. The supporting substrate 30 may be bonded through the bonding layer 305 on the device substrate 200 of the integrated circuit substrate structure 20.

According to some example embodiments, the supporting substrate 30 may be a glass substrate, a ceramic substrate, or a plastic substrate, but embodiments are not limited thereto. For example, in some example embodiments, the supporting substrate 30 may include a resin impregnated in a core material such as glass fiber (e.g., glass cloth and/or glass fabric) with an inorganic filler, for example, prepreg, an Ajinomoto build-up film (ABF), FR-4, or Bismaleimide Triazine (BT).

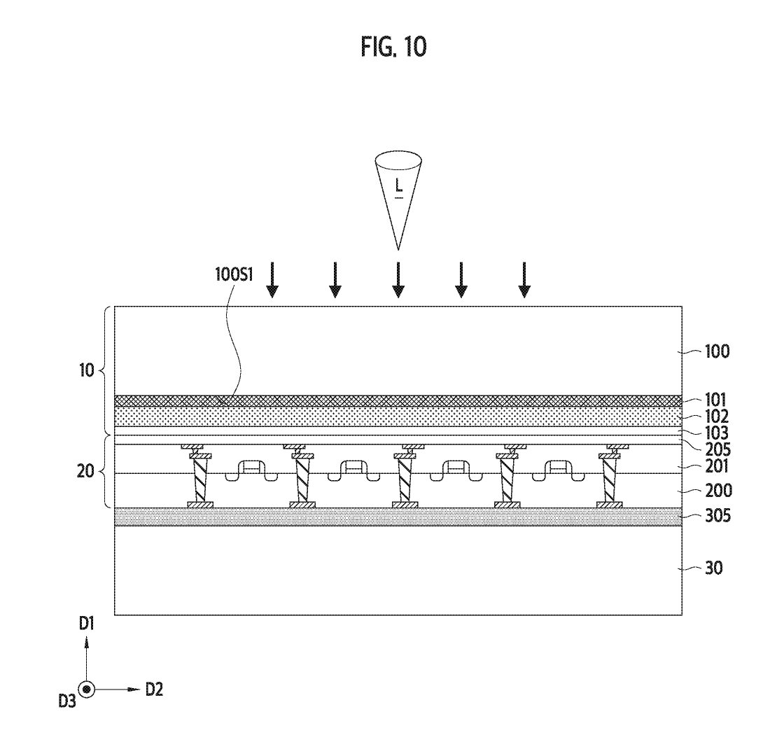

Referring to FIG. 10, light may be provided on the carrier substrate structure 10. In an example embodiment, the light may have a wavelength of 9000 nm or greater. For example, in some example embodiments, the light may have a wavelength in the infrared range of 9300 nm or greater. The supporting substrate 30 may support the integrated circuit substrate structure 20, and the carrier substrate structure 10 may be exposed to the light from a light source L. In order to expose the carrier substrate structure 10 to the light source L, a structure in which the supporting substrate 30, the integrated circuit substrate structure 20 and the carrier substrate structure 10 are stacked may be flipped in the first direction D1 in order for the supporting substrate 30 to be placed under the integrated circuit substrate structure 20 and the carrier substrate structure 10.

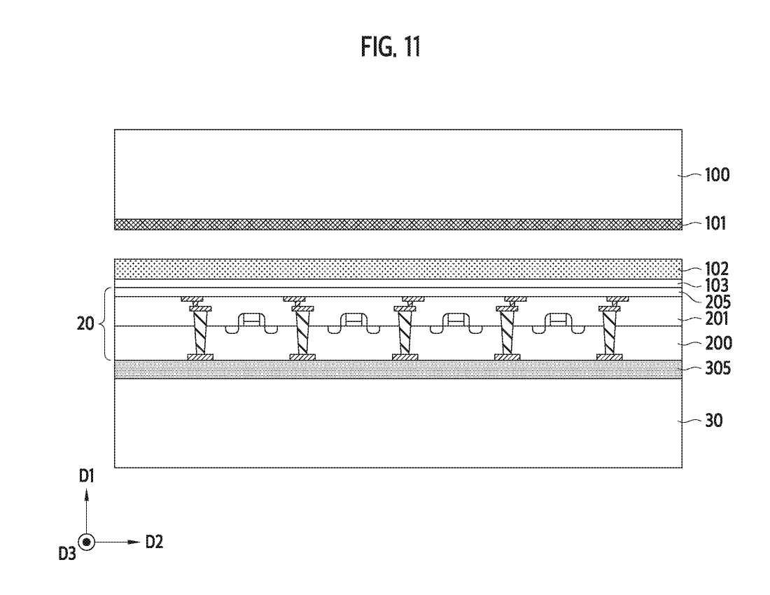

Referring to FIG. 11, the de-bonding layer 101 and the light absorbing layer 102 may be separated by the provided light from the light source L. The de-bonding layer 101 and the light absorbing layer 102 may be separated at the interface therebetween. There is the difference in the thermal expansion degree between the de-bonding layer 101 and the light absorbing layer 102 due to heat from the provided light, and thus the de-bonding layer 101 and the light absorbing layer 102 may be separated at the interface. As the de-bonding layer 101 and the light absorbing layer 102 are separated, the carrier substrate 100 and the de-bonding layer 101 may be separated from the integrated circuit substrate structure 20. The bonding layer 103 and the light absorbing layer 102 bonded to the bonding layer 205 of the integrated circuit substrate structure 20 may be maintained on the bonding layer 205 without being separated from the integrated circuit substrate structure 20.

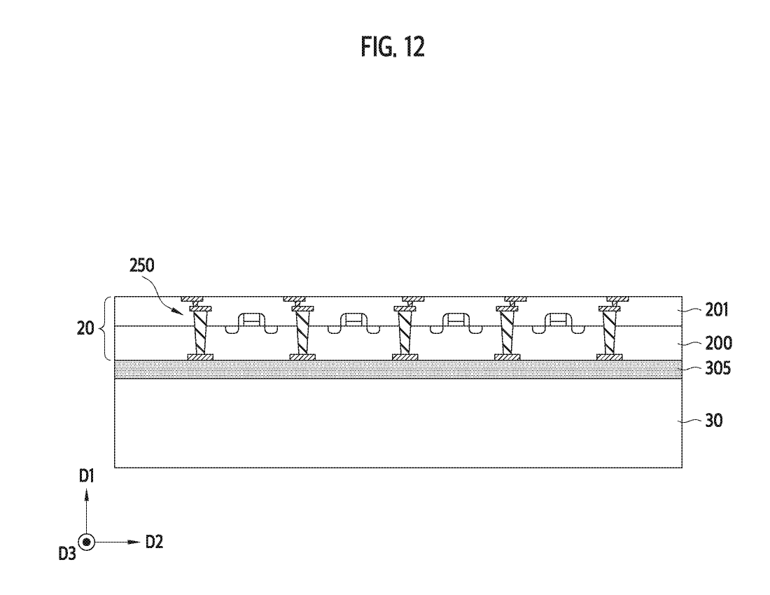

Referring to FIG. 12, the bonding layer 103 (of FIG. 11) and the light absorbing layer 102 (of FIG. 11) of the carrier substrate structure 10 bonded to the bonding layer 205 (of FIG. 11) of the integrated circuit substrate structure 20 may be removed. In some example embodiments, the bonding layer 205 and the bonding layer 103 (of FIG. 11) covering the integrated circuit substrate structure 20 bonded on the supporting substrate 30, and the light absorbing layer 102 (of FIG. 11) may be removed. For example, the integrated circuit device 250 may be exposed by the bonding layer 205 (of FIG. 11), the bonding layer 103 (of FIG. 11) and the light absorbing layer 102 (of FIG. 11) being removed.

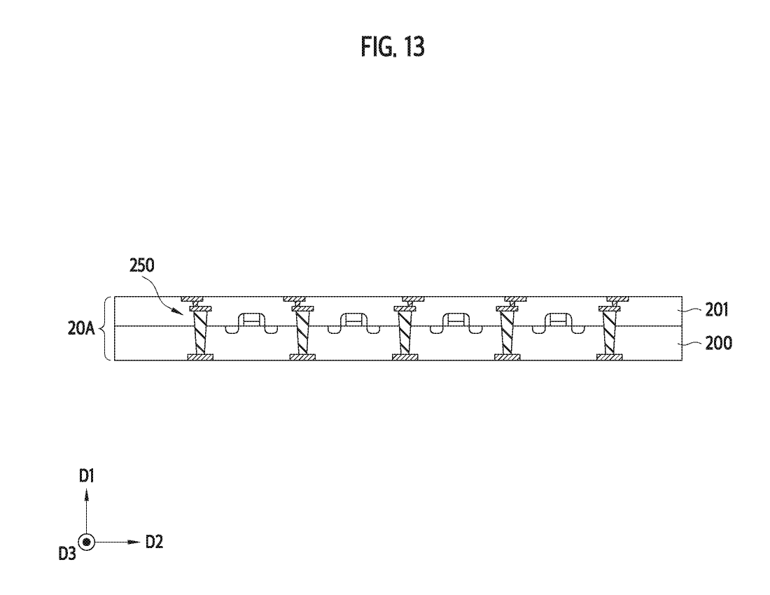

Referring to FIG. 13, the supporting substrate 30 (of FIG. 12) and the bonding layer 305 (of FIG. 12) may be removed and an integrated circuit device 20A may be formed. For example, in an example embodiment, the supporting substrate 30 (of FIG. 12) and the bonding layer 305 (of FIG. 12) may be removed through the CMP process.

According to various embodiments described above, a carrier substrate structure may be provided according to various implementations.

### Implementation 1

A carrier substrate structure may comprise a carrier substrate; a de-bonding layer that is placed on the carrier substrate, the de-bonding layer comprising and comprises a metallic oxide; a light absorbing layer that is placed on the de-bonding layer, the light absorbing layer comprising and comprises a silicon oxide; and a bonding layer on the light absorbing layer.

### Implementation 2

The carrier substrate structure of implementation 1, wherein the de-bonding layer has a thermal expansion coefficient that is 10 times or greater than 10 times of a thermal expansion coefficient of the light absorbing layer or greater.

### Implementation 3

The carrier substrate structure of implementation 1 or 2, wherein an interface between the de-bonding layer and the light absorbing layer is configured to be separated by light with a wavelength of 9300 nm or greater.

### Implementation 4

The carrier substrate structure of one of implementations 1-3, further comprising a protecting layer that comprises a metal material, and is placed between the light absorbing layer and the bonding layer, the protecting layer comprising a metal material.

### Implementation 5

The carrier substrate structure of one of implementations 1-4, wherein the protecting layer reflects light with a wavelength of 9300 nm or greater.

### Implementation 6

The carrier substrate structure of one of implementations 1-5, further comprising a buffer layer that comprises a silicon oxide, and is placed between the protecting layer and the bonding layer, the buffer layer comprising a silicon oxide.

### Implementation 7

The carrier substrate structure of one of implementations 1-6, wherein a thickness of the buffer layer is greater than a thickness of the protecting layer.

### Implementation 8

The carrier substrate structure of one of implementations 1-7, wherein the protecting layer comprises one of titanium nitride, tungsten, aluminum and or copper.

### Implementation 9

The carrier substrate structure of one of implementations 1-8, wherein a thickness of the protecting layer is in a range of about 5 nm to about 50 nm.

### Implementation 10

The carrier substrate structure of one of implementations 1-9, wherein the de-bonding layer is in contacts with the carrier substrate.

### Implementation 11

The carrier substrate structure of one of implementations 1-10, wherein the de-bonding layer absorbs light with a wavelength of 9300 nm or greater.

### Implementation 12

The carrier substrate structure of one of implementations 1-11, wherein the de-bonding layer has a thickness in a range of about 5 nm to about 100 nm.

### Implementation 13

The carrier substrate structure of one of implementations 1-12, wherein the light absorbing layer has a thickness that is in a range of about 100 nm to about 500 nm.

In the above description, various embodiments are described in detail. However, it will be apparent to those of ordinary skill in the technical field that is the embodiments are not limited thereto, and that various modifications and variations are possible without departing from the technical spirit of the present disclosure as set forth in the claims. Further, the above-described example embodiment may be implemented with some elements deleted, and various example embodiments may be implemented in combination with each other. All such modifications are intended to be included in the scope of the appended claims.

What is claimed is:

1. A method of manufacturing an integrated circuit device, the method comprising:
forming a de-bonding layer on a carrier substrate, the de-bonding layer comprising a metallic oxide;
forming a light absorbing layer on the de-bonding layer;
forming a bonding layer on the light absorbing layer;
bonding an integrated circuit substrate structure to the bonding layer; and
irradiating the carrier substrate with light to separate the de-bonding layer from the light absorbing layer,
wherein the de-bonding layer has a thermal expansion coefficient that is 10 times or greater than 10 times a thermal expansion coefficient of the light absorbing layer.

2. The method of claim 1, further comprising forming a device structure on the integrated circuit substrate structure, the device structure being electrically connected with the integrated circuit device on the integrated circuit substrate structure.

3. The method of claim 1, wherein the light has a wavelength of 9300 nm or greater.

4. The method of claim 1, further comprising, before forming the bonding layer, forming a protecting layer on the light absorbing layer, the protecting layer comprising a metal material.

5. The method of claim 4, wherein the protecting layer reflects light with a wavelength of 9300 nm or greater.

6. The method of claim 4, further comprising, after forming the protecting layer, forming a buffer layer on the protecting layer, the buffer layer comprising a silicon oxide.

7. The method of claim 6, wherein the buffer layer is formed to have a first thickness and the protecting layer is formed to have a second thickness, and wherein the first thickness is greater than the second thickness.

8. The method of claim 4, wherein the protecting layer comprises one of titanium nitride, tungsten, aluminum or copper.

9. The method of claim 4, wherein the protecting layer is formed to have a thickness of about 5 nm to about 50 nm.

10. The method of claim 1, wherein the de-bonding layer absorbs light with a wavelength of 9300 nm or greater.

11. The method of claim 1, wherein the de-bonding layer is formed to have a thickness of about 5 nm to about 100 nm.

12. The method of claim 1, wherein the light absorbing layer is formed to have a thickness of about 100 nm to about 500 nm.

13. A method of manufacturing an integrated circuit device, the method comprising:
forming a carrier substrate structure comprising a de-bonding layer, a light absorbing layer and a bonding layer that are sequentially stacked on a carrier substrate;
bonding an integrated circuit substrate structure on the bonding layer, the integrated circuit substrate structure comprising the integrated circuit device;
forming a device structure on the integrated circuit substrate structure, the device structure being electrically connected with the integrated circuit device; and
irradiating the carrier substrate structure with light to de-bond the de-bonding layer and the light absorbing layer,
wherein the de-bonding layer comprises a metallic oxide, and
wherein the de-bonding layer has a thermal expansion coefficient that is 10 times or greater than 10 times a thermal expansion coefficient of the light absorbing layer.

14. The method of claim 13, wherein the light has a wavelength that is 9300 nm or greater.

15. The method of claim 13, wherein the de-bonding layer comprises one of TiO or AlO.

16. The method of claim 13, further comprising, after the de-bonding layer is de-bonded from the light absorbing layer, removing the light absorbing layer and the bonding layer.

17. The method of claim 13, wherein the carrier substrate structure further comprises a protecting layer between the light absorbing layer and the bonding layer, the protecting layer comprising a metal material that reflects the light.

18. The method of claim 13, wherein in de-bonding the de-bonding layer from the light absorbing layer, the bonding layer and the light absorbing layer remain bonded with the integrated circuit substrate structure.

19. A method of manufacturing an integrated circuit device, the method comprising:
bonding an integrated circuit substrate structure on a carrier substrate structure comprising a de-bonding layer, a light absorbing layer, a protecting layer, a buffer layer and a bonding layer that are sequentially stacked on a carrier substrate, the integrated circuit substrate structure comprising the integrated circuit device; and
irradiating the carrier substrate structure with light having a wavelength of 9300 nm or greater to de-bonding the de-bonding layer from the light absorbing layer,
wherein the de-bonding layer comprises a metallic oxide,
wherein the de-bonding layer has a thermal expansion coefficient that is 10 times or greater than 10 times a thermal expansion coefficient of the light absorbing layer,
wherein the de-bonding layer and the light absorbing layer absorb the light, and
wherein the protecting layer reflects the light.

20. The method of claim 19, further comprising forming a device structure on the integrated circuit substrate structure, the device structure being electrically connected with the integrated circuit device on the integrated circuit substrate structure.
